(19) United States
(12) Patent Application Publication
(10) Pub. No.: US 2026/0190259 A1
(43) Pub. Date: Jul. 2, 2026

(54) EMERGENCY STATION COVERS AND RELATED METHODS OF USE

(71) Applicants: Brian Bowles, Salt Lake City, UT (US); Theodore R. Espiritu, Jr., Salt Lake City, UT (US); Colter Turley, Ogden, UT (US); Austin B. Harker, Murray, UT (US); Daniel H. Stuart, Layton, UT (US); Samantha Tan, Salt Lake City, UT (US)

(72) Inventors: Brian Bowles, Salt Lake City, UT (US); Theodore R. Espiritu, Jr., Salt Lake City, UT (US); Colter Turley, Ogden, UT (US); Austin B. Harker, Murray, UT (US); Daniel H. Stuart, Layton, UT (US); Samantha Tan, Salt Lake City, UT (US)

(21) Appl. No.: 19/433,497

(22) Filed: Dec. 26, 2025

Related U.S. Application Data
(60) Provisional application No. 63/741,348, filed on Jan. 2, 2025.

(51) Int. Cl. H05K 5/02

(52) U.S. Cl. CPC H05K 5/0247; H05K 5/0226

(57) ABSTRACT

Embodiments disclosed relate to emergency station covers and related systems and methods of use. A cover for an emergency alert station includes a base, an intermediate member, and a cover member. The base includes a plate defining a slot extending from a bottom of the base towards a top of the base, with the slot being sized to fit around a portion of the emergency station cover. The intermediate member is secured to the base with a first living hinge. The cover member is secured to the intermediate member with a second living hinge. The cover is selectively adjustable between a closed configuration in which the cover member covers the base and an open configuration in which the base is substantially free of coverage from the cover member.

### RELATED APPLICATIONS

This application claims priority to U.S. Provisional Application No. 63/741,348, filed on Jan. 2, 2025, and titled EMERGENCY STATION COVERS AND RELATED METHODS OF USE, which is incorporated herein by reference in its entirety.

### FIELD OF THE INVENTION

This application generally relates to selectively adjustable covers for code blue emergency stations that include an actuator and/or buttons for activating a code blue emergency alert in a hospital setting, and related methods of use.

### BACKGROUND

In a typical hospital setting, patient rooms and other areas include a code blue emergency station. These code blue stations typically include an actuator and/or a button for activating a code blue emergency alert in the hospital. A code blue emergency alert notifies healthcare professionals that a patient is in critical condition and requires immediate medical attention. The actuator and/or button of code blue emergency stations, however, is often inadvertently or accidently contacted to erroneously activate a code blue emergency alert.

### SUMMARY

Embodiments disclosed herein include emergency station covers and related systems and methods of use. In an embodiment, a cover for an emergency alert station includes a base, an intermediate member, and a cover member. The base includes a first base end region, a second base end region, and a plate defining a slot extending from the first base end region towards the second base end region. The slot is sized to fit around a portion of the emergency station cover. The intermediate member is secured to the second end region of the base with a first living hinge. The cover member has a first cover end region and a second cover end region secured to the intermediate member with a second living hinge. The cover is selectively adjustable between a closed configuration in which the cover member covers the base and an open configuration in which the base is substantially free of coverage from the cover member.

In an embodiment, an emergency station cover assembly includes an emergency alert station and a cover. The emergency alert station includes a station base configured to electrically couple to one or more wires or cables. The station base includes a station plate, a station body extending from the station plate, a screw hole positioned on the station plate to secure the station base to a structure, and at least one of an actuator or a button configured to electrically couple to the one or more wires or cables. The cover is secured or securable to the emergency alert station and includes a base, an intermediate member, and a cover member. The base includes a first base end region, a second base end region, and a plate defining a slot extending from the first base end region towards the second base end region. The slot is sized to fit around a portion of the station base. The intermediate member is secured to the second end region of the base with a first living hinge. The cover member has a first cover end region and a second cover end region secured to the intermediate member with a second living hinge. The cover is selectively adjustable between a closed configuration in which the cover member covers the emergency alert station and an open configuration in which the emergency alert station is substantially free of coverage from the cover member.

In an embodiment, a method of securing a cover to an emergency alert station includes positioning a portion of a station body of a station base of the emergency alert station within a slot defined by a plate of a cover base of the cover. The slot extends from a first base end region of the cover base towards a second base end region of the base, the station base being electrically coupled or coupleable to one or more wires or cables and including at least one of an actuator or a button electrically coupled or coupleable to the one or more wires or cables. The method also includes positioning a screw or nail through a notch in the plate of the cover base, the screw or nail being disposed through a hole in a station plate of the station base. The method also includes adjusting the cover from an open position in which the emergency alert station is at least partially free of coverage from a cover member of the cover to a closed position in which the cover member covers the emergency alert station. In the closed position, an intermediate member secured between the cover member and the cover base is (1) angled relative to the cover base through a first living hinge connecting the intermediate member and the cover base and (2) angled relative to the cover member through a second living hinge connecting the intermediate member and the cover member.

Features from any of the disclosed embodiments may be used in combination with one another, without limitation. In addition, other features and advantages of the present disclosure will become apparent to those of ordinary skill in the art through consideration of the following detailed description and the accompanying drawings.

### BRIEF DESCRIPTION OF THE DRAWINGS

The drawings illustrate several embodiments of the present disclosure, wherein identical reference numerals refer to identical or similar elements or features in different views, or embodiments shown in the drawings.

FIGS. 1A-1B are isometric views of an emergency station cover in an open position, according to an embodiment.

FIGS. 2A-2B are isometric views of the emergency station cover of FIGS. 1A-1B in a closed position, according to an embodiment.

FIG. 3A is a rear view of an emergency station and cable.

FIG. 3B is an exploded isometric view of an emergency station.

FIG. 3C is an isometric view of the emergency station cover of FIGS. 1A-1B in the open position and secured to an emergency station, according to an embodiment.

FIG. 3D is an isometric view of the emergency station cover FIGS. 1A-1B in the closed position and secured to the emergency station, according to an embodiment.

FIG. 4 is a flowchart of a method of securing a cover to an emergency alert station, according to an embodiment.

### DETAILED DESCRIPTION

Emergency station covers and related methods of use are disclosed herein. In hospital settings, patient rooms and other areas include a code blue emergency station. These code blue stations typically include an actuator and/or a button for activating a code blue emergency alert in the hospital. A code blue emergency alert notifies healthcare professionals that a patient is in critical condition and requires immediate medical attention. The actuator and/or button of code blue emergency stations, however, is often inadvertently or accidently contacted to erroneously activate a code blue emergency alert. The emergency station covers disclosed herein are selectively adjustable to cover code blue emergency stations to prevent accidental or unintended activation of a code blue. The emergency station covers disclosed herein also are configured to retrofit preexisting code blue emergency stations without disconnecting the wiring or cables of the code blue emergency stations. This allows for quicker and simpler installation of the emergency station covers disclosed herein. In many embodiments, the emergency station covers disclosed herein include two living hinges that are positioned such that the cover does not contact or interfere with an actuator and/or button of the emergency station. The emergency station cover also may include interlocking or coupleable tabs which hold the cover closed, but also allow the cover to be easily opened in an emergency.

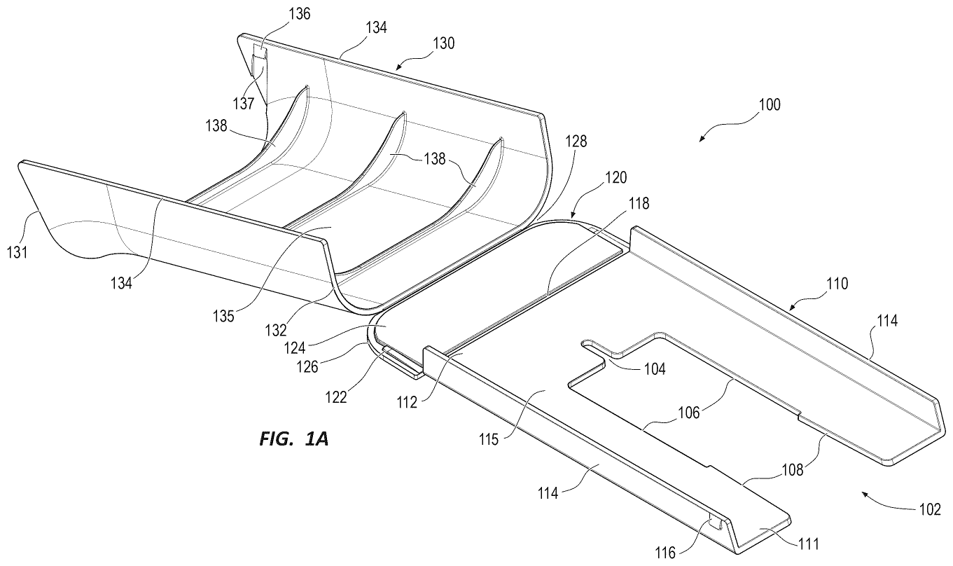

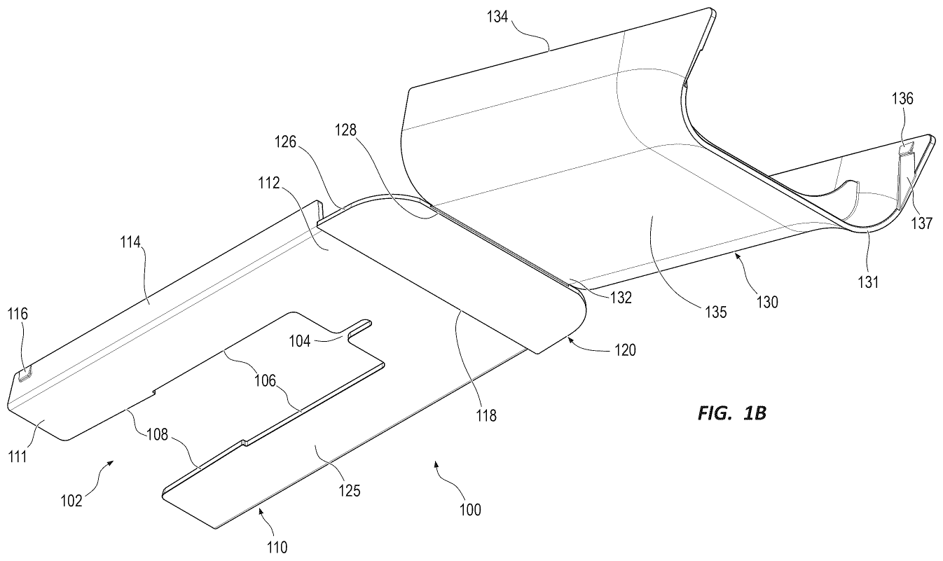

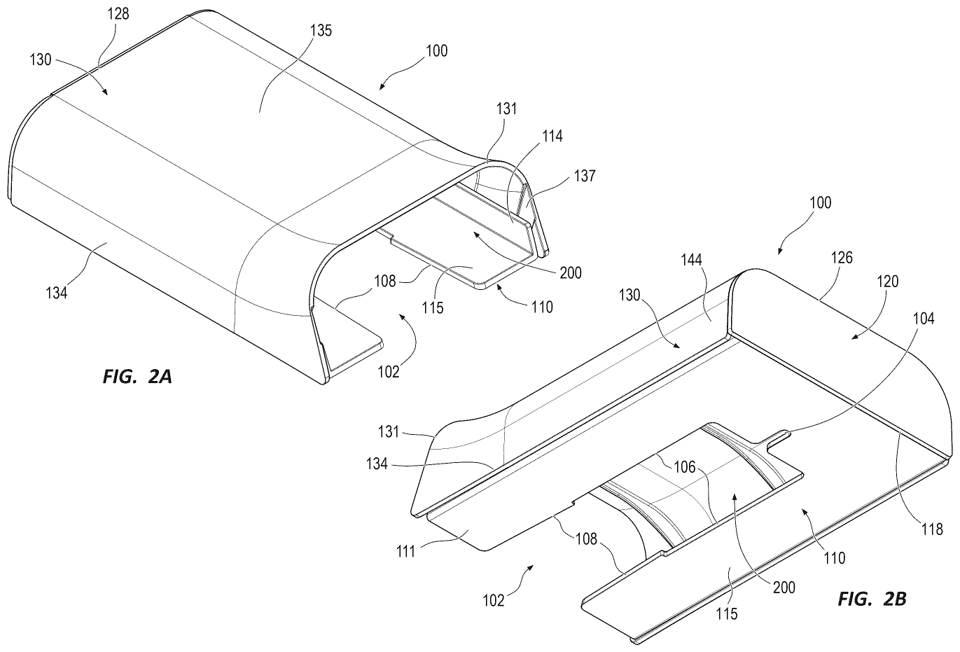

Turning to the drawings, FIGS. 1A-2B are views of an emergency station cover 100 that is selectively adjustable between an open position and a closed position. The emergency station cover 100 is configured to be secured to a code blue emergency station without disconnecting and/or re-wiring the code blue emergency station. FIGS. 1A-1B are isometric views of an emergency station cover in an open position, according to an embodiment. In many embodiments, the emergency station cover 100 includes a base 110 (e.g., cover base), an intermediate member 120 secured to the base 110, and a cover member 130 secured to the intermediate member 120 such that the intermediate member 120 is disposed between the cover member 130 and the base 110. The base 110, the intermediate member 120, and the cover member 130 may be formed as a single, one-piece cover. Conventional cover assemblies typically require multiple pieces secured together with hardware. The single, one-piece cover 100 disclosed herein is easier to clean, as debris will not build up around hardware securing two pieces together (as occurs in conventional cover assemblies). Additional, in conventional instances where the hardware includes metal screws, said metal screws can corrode over time. Moreover, issues of hardware becoming loose and/or lost is not an issue in a single, one-piece cover 100 as disclosed herein. In some embodiments, the cover 100 is a clear or transparent material. In other embodiments, the cover 100 is a semi-transparent material.

The base 110 may include a first base end region 111 (e.g., a base bottom region), a second base end region 112 (e.g., a base top region), and a plate 115 defining a slot 102 extending from the first base end region 111 towards the second base end region 112. In many embodiments, the plate 115 is substantially planar or flat. The base 110 also may include two opposing base sidewalls 114 extending at least partially between the first base end region 111 and the second base end region 112. The plate 115 and the slot 102 defined by the plate 115 may be positioned between the two opposing base sidewalls 114. In some embodiments, the sidewalls 114 are substantially perpendicular to the plate 115.

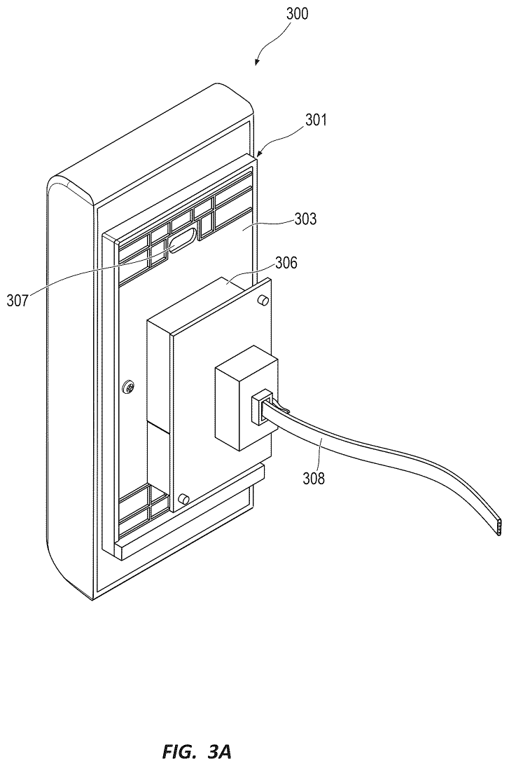

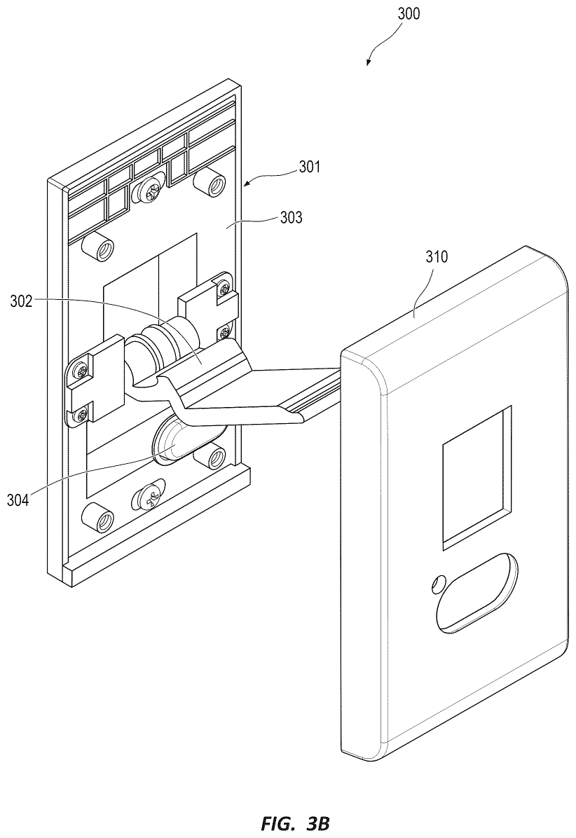

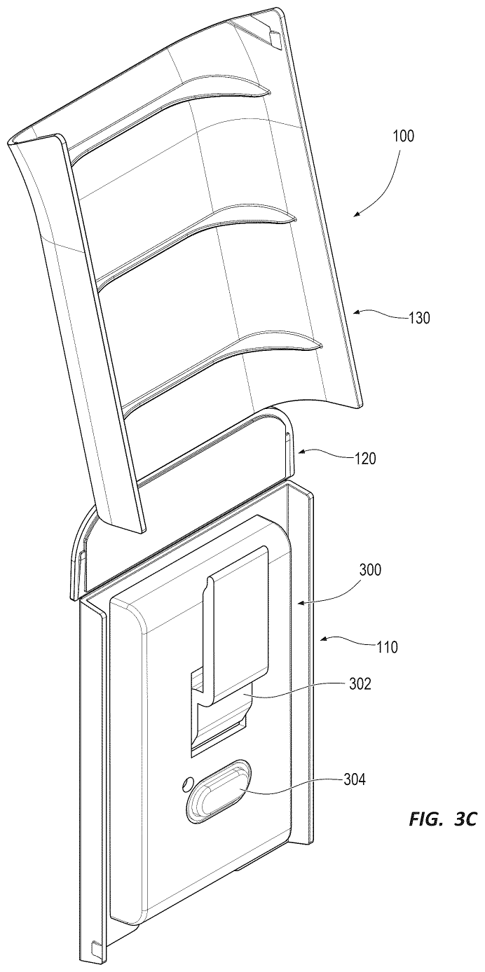

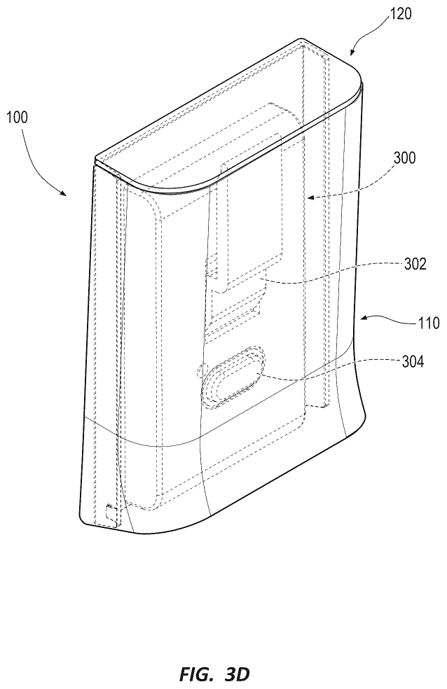

The slot 102 is sized to fit around a portion of the emergency station cover, such as the station body 306 of the emergency station cover 300 shown in FIG. 3A. In some embodiments, the slot 102 defined by the plate 115 includes a first portion 108 (e.g., a bottom portion) and a second portion 106 (e.g., a top portion). The first portion 108 is disposed proximate to the first base end region 111 and has a first width. The second portion 106 is spaced from the first base end region 108 and has a second width that is greater than the first width. Said another way, the bottom or first portion 108 of the slot 102 is narrower than the top or second portion 106 of the slot 102. Accordingly, the plate 115 defining the slot 102 may include opposing inward extending lips or edges at the bottom or first portion 108 of the slot 102. In many embodiments, the second portion 106 of the slot 102 is sized such that at least a portion of the station base 306 of a standard emergency station 300 fits within the second portion 106 of the slot 102, and the plate 115 snap fits around at least a portion of the station base 306 at the inward extending lips or edges of the bottom or first portion 108 of the slot 102. The plate 115 may have sufficient flexibility to allow the station base 306 to slide within the slot 102 until at least a portion of the station base 306 is positioned within the second portion 106 of the slot and the plate 115 engages around at least a portion of the station base 306 at the first portion 108 of the slot 102.

The slot 102 defined by the plate 115 also may include a notch 104 proximate to or near the second portion 106 of the slot 102. For example, the notch 104 may be positioned near the top or second end region 112 of the base 110 and/or positioned with the top or second portion 106 of the slot 102 between the notch 104 and the bottom or first portion 108 of the slot 102. The notch 104 may extend from the second portion 106 of the slot 102 towards the intermediate member 120. The notch 104 is sized to allow a screw or other fastener to pass through. For example, the notch 104 may be positioned to align with a screw hole on the emergency station. At least one (e.g., both) base sidewall of the two opposing base sidewalls 114 may include a base tab 116 positioned on an outer surface of the at least one base sidewall. The base tab 116 may extend outward from the outer surface of the sidewall 114.

The intermediate member 120 may be secured to the second end region 112 of the base 110 with a first living hinge 118. The first living hinge 118 is configured to bend effective to allow the intermediate member 120 to selectively pivot or swing between a position that is substantially parallel and/or coplanar with the plate 115 (e.g., when the cover 100 is in the open position) and a position that is substantially perpendicular to the plate 115 (e.g., when the cover 100 is in the closed position).

In some embodiments, the two opposing base sidewalls 114 are sized and positioned at the second base end region 112 of the base 110 such that the intermediate member 120 contacts the two opposing base sidewalls 114 when the cover 100 is in the closed position. For example, the intermediate member 120 may include one or more alignment features 122 positioned on the intermediate member 120 to contact the two opposing base sidewalls 114 when the cover 100 is in the closed position. The one or more alignment features 122 may be configured to position the intermediate member 120 substantially perpendicular to the plate 115 of the base 110 in the closed position. The intermediate member 120 also may include an indexing feature 124 configured to assist with aligning the intermediate member 120 with the base 110 and the cover member 130 in the closed position. The one or more alignment features 122 and/or the indexing feature 124 may be raised or protrude from the body of the intermediate member 120, with the indexing feature 124 being raised more than the one or more alignment features 122, according to an embodiment. When the cover 100 is in the closed position, the one or more alignment features 122 rest on the top edge of the base sidewall(s) 114 of the base 110, which may provide the primary support for both the intermediate member 120 and the cover member 130 in the closed position. Also, when the cover 100 is in the closed position, the body of the intermediate member 120 may rest against the top or second end region 132 of the cover member 130.

The intermediate member 120 may be wider than the base 110 and/or wider than a distance between the two opposing base sidewalls 114 of the base 100. Accordingly, when the cover 100 is in the closed position, the intermediate member 110 may include a perimeter or periphery 126 that extends outward beyond the two opposing base sidewalls 114. The periphery 126 of the intermediate member 120 may be shaped generally complementary to a top or second end region 132 of the cover member 130.

The cover member 130 may include a bottom or first cover end region 131, a top or second cover end region 132 that is secured to the intermediate member 120 with a second living hinge 128, two opposing cover sidewalls 132 extending at least partially between the first cover end region 131 and the second cover end region 132, and a cover body 135 positioned between the two opposing cover sidewalls 134. In some embodiments, the cover body 135 is substantially planar. The second living hinge 128 may extend laterally along the cover body 135 between the cover member 130 and the intermediate member 120. The second living hinge 128 is configured to bend effective to allow the cover member 130 to selectively pivot or swing between a position having the cover body 135 substantially parallel and/or coplanar with the intermediate member 120 and/or the plate 115 (e.g., when the cover 100 is in the open position) and a position having the cover body 135 substantially perpendicular to intermediate member 120 and substantially parallel to the plate 115 (e.g., when the cover 100 is in the closed position).

The cover member 130 also may include one or more support member 138 on an inner surface of the cover member 130 and extending along cover body 135 between the two opposing sidewalls 134. In some embodiments, the opposing sidewalls 134 include a portion that is substantially perpendicular to the cover body 135. The opposing sidewalls 134 also may include a curved region extending between the cover body 135 and the portion that is substantially perpendicular to the cover body 135. In some embodiments, the first end region 131 of the cover member 130 may be flared or wider than the second end region 132 of the cover member 130. At least one (e.g., both) cover sidewall of the two opposing cover sidewalls 134 may include a cover tab 136 positioned on an inner surface of the at least one cover sidewall to engage with the base tab 116 when the cover 100 is in the closed position. The inner surface of the first end region 131 also may include a channel or groove 137 positioned to receive the base tab 116 when the cover 100 is in the closed position. Engagement of the cover tab 136 and the base tab 116 can aid in maintaining the cover 100 in the closed position absent the application of a threshold force by a user to open the cover 100.

The cover 100 is selectively adjustable between the open configuration shown in FIGS. 1A-1B in which the base 110 is substantially free of coverage from the cover member 130, and the closed configuration in which the cover member 130 covers the base 110. FIGS. 2A-2B, for example, are isometric views of the emergency station cover of FIGS. 1A-1B in the closed position, according to an embodiment. When the cover 100 is in the closed position, the two opposing cover sidewalls 134 space the cover body 135 from the plate 115 of the base 110. For example, the plate 115 of the base 110 and the cover member 130 may define an interior region 200 of the cover 100 in the closed position. The interior region 200 may be sized to position at least a portion of the emergency alert station therein without the cover member 130 contacting the emergency alert station.

As noted above, at least one cover sidewall of the two opposing cover sidewalls 114 may include a cover tab 116 positioned on an inner surface of the at least one cover sidewall to engage with the base tab 136 and be positioned within the channel or groove 137 when the cover 100 is in the closed position. The first living hinge 118 may be configured to bend such that the plate 115 is substantially perpendicular with the intermediate member 120 when the cover 100 is in the closed position. The second living hinge 128 may be configured to bend such that the cover body 135 is substantially perpendicular with the intermediate member 120 when the cover 100 is in the closed position. As shown in FIGS. 2A-2B, the second cover end region 131 may be shaped complementary to the intermediate member 120 such that, in the closed position, the perimeter 126 of the intermediate member 120 is substantially aligned with the cover body 135 and the opposing sidewalls 134 at the second cover end region 132 of the cover member 130.

The cover 100 is selectively adjustable between the open position and the closed position to cover a code blue emergency station to prevent accidental or unintended activation of a code blue. As noted above, the cover 100 may be configured to retrofit preexisting code blue emergency stations without disconnecting the wiring or cables of the code blue emergency stations. This allows for quicker and simpler installation of the cover 100. For example, FIG. 3A is a rear view of an emergency station 300 and a cable 308 connected thereto, and FIG. 3B is an exploded isometric view of an emergency station 300. The cover 100 may be configured to secure to the emergency station 300 without disconnecting the cable 308 from the emergency station. The emergency station 300 may include a station base 301 configured to electrically couple to the one or more wires or cables 308. The station base 301 may include a station plate 303, a station body 306 extending from the station plate 303, a screw hole 307 positioned on the station plate to secure the station base to a structure, and at least one of an actuator 302 or a button 304 configured to electrically couple to the one or more wires or cables 308. The emergency station 300 also may include a cover piece 310 configured to secure to the station base 301. The cover piece 310 may include one or more apertures positioned for access of the at least one of the actuator 302 or the button 304 therethrough.

FIG. 3C is an isometric view of the cover 100 in the open position and secured to an emergency station, and FIG. 3D is an isometric view of the cover 100 in the closed position and secured to the emergency station 300, according to an embodiment. The cover 100 is selectively adjustable between a closed configuration in which the cover member 130 covers the emergency alert station and the open configuration in which the emergency alert station 300 is substantially free of coverage from the cover member 130. In many embodiments, the living hinges 118, 128 of the cover 100 are positioned such that the cover 100 does not contact or interfere with actuator 302 and/or button 304 of the emergency station 300 when the cover 100 is in the closed position with the cover member 130 covering the emergency station 300.

The slot 102 may be sized to fit around a portion of the station base 306. For example, the slot 102 may be sized and shaped to snap fit around the portion of the station base 306 with the station base 306 positioned within the second portion 106 of the slot 102. The notch 104 on the plate 115 may be positioned to align with the screw hole 307 of the station plate 303. The notch 104 may be sized to allow a screw to pass therethrough, effective allow the station plate 303 to be secured to a support structure (e.g., a junction box) with the plate 115 positioned between the station plate 303 and the support structure. The cover piece 310 and the station plate 303 may be sized to fit between the two opposing base sidewalls 114. When the cover 100 is in the closed position, the two opposing cover sidewalls 134 space the cover body 135 from the plate 115 of the base 110. In the closed position, the plate 115 of the base 110 and the cover member 130 may define the interior region 300 of the cover 100. At least one of the actuator 302 or the button 304 of the emergency alert station 300 may be positioned within the interior region 300 without the cover member 130 contacting the at least one of the actuator 302 or the button 304.

In certain embodiments, the living hinges 118, 128 and the cover body 135 are configured such that gravity can cause and/or keep the cover 100 in the closed position absent the application of force by a user. During a code blue emergency, a user can insert a portion of their hand (e.g., one or more fingers) into an opening defined by the cover body 135 and the plate 115, and lift the cover body 135 upwards. As shown in FIG. 2A, the opening can be disposed opposite the intermediate member 120, and proximate the first cover end region 131 and first base end region 111. The opening can provide access to the interior region 200 of the cover 100. When a threshold force is applied by the user, the cover body 135 can be lifted by causing the cover tab(s) 136 and base tab(s) 116 to disengage from one another. When lifted, the living hinges 118, 128 can allow the cover body 135 to be disposed upward and/or away from the emergency station actuator 302 or button 304 such that the cover body 135 does not interfere with grasping of the actuator 302 or pressing of the button 304 by the user. Release of the cover body 135 by the user can then cause the cover body 135, intermediate member 120, and living hinges 118, 128 to fold the cover 100 back into the closed position.

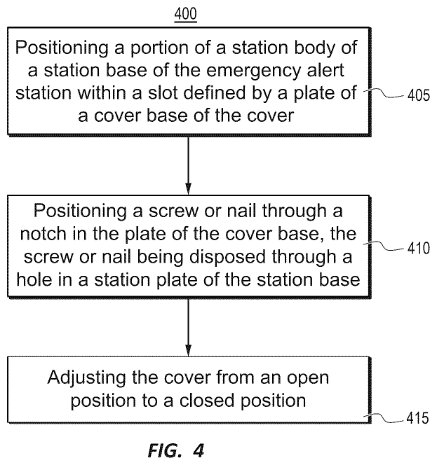

FIG. 4 is a flowchart of a method 400 of securing the cover 100 to the emergency alert station 300, according to an embodiment. The method 400 may include positioning 405 a portion of the station body 306 of the station base 301 of the emergency alert station 300 within the slot 102 defined by the plate 115 of the base 110 of the cover 100. In some embodiments, this can include loosening a screw (with or without full removal of the screw) that couples the station base 301 to a structure, and then sliding the plate 115 of the cover behind the station base 301 such that the station body 306 is disposed in the slot 102. The method 400 also may include positioning 410 a screw or nail through a notch 104 in the plate 115 of the cover base 110, the screw or nail being disposed through a hole in a station plate 303 of the station base 301. In some embodiments, this can include tightening a screw once the plate 115 has been slid behind the station base 301. The cover piece 310 may thereafter be coupled to the station base 301. The method 400 also may include adjusting 415 the cover 100 from the open position in which the emergency alert station 300 is at least partially free of coverage from the cover member 130 of the cover 100 to a closed position in which the cover member covers the emergency alert station 300. In the closed position, the intermediate member 120 secured between the cover member 130 and the base 110 is (1) angled relative to the base 110 through the first living hinge 118 connecting the intermediate member 120 and the base 110 and (2) angled relative to the cover member 130 through the second living hinge 128 connecting the intermediate member 120 and the cover member 130.

In some embodiments of the method 400, positioning 405 a portion of the station body 306 within the slot 102 defined by the plate 115 includes positioning the station body 306 within the second portion 106 of the slot 102. When the cover 100 is adjusted to the closed position in the method 400, the two opposing cover sidewalls 134 space the cover body 135 from the plate 115 of the base 110, with the plate 115 of the base 110 and the cover member 130 defining an interior region 300 of the cover 100. The interior region 300 in the closed position in the method 400 is sized to position the at least one of the actuator 302 or the button 304 of the emergency alert station 300 therein without the cover member 130 contacting the at least one of the 302 actuator or the button 304. In many embodiments of the method 400, the station base 306 is electrically coupled to the one or more wires or cables 308. The steps of the method 400 of (1) positioning 405 the portion of the station body 306 within the slot 102 defined by the plate 115 of the base 110, (2) positioning 410 a screw or nail through a notch 104 in the plate 115 of the cover base 110, the screw or nail being disposed through a hole in a station plate 303 of the station base 301, and (3) adjusting 415 the cover 100 from the open position to the closed position are performed without disconnecting the one or more wires or cables 308 from the station base 306.

Acts of the method 400 are for illustrative purposes. For example, the acts of the method 400 may be performed in different orders, split into multiple acts, modified, supplemented, or combined. Any of the acts of the method 400 may include using any of the covers 100 or systems disclosed herein.

As used herein, the term “about” or “substantially” refers to an allowable variance of the term modified by “about” by ±10% or ±5%. Further, the terms “less than,” “or less,” “greater than,” “more than,” or “or more” include as an endpoint, the value that is modified by the terms “less than,” “or less,” “greater than,” “more than,” or “or more.”

While various aspects and embodiments have been disclosed herein, other aspects and embodiments are contemplated. The various aspects and embodiment disclosed herein are for purposes of illustration and are not intended to be limiting.

1. A cover for an emergency alert station, the cover comprising:
a base comprising a first base end region, a second base end region, and a plate defining a slot extending from the first base end region towards the second base end region, wherein the slot is sized to fit around a portion of the emergency station cover;
an intermediate member secured to the second end region of the base with a first living hinge; and
a cover member having a first cover end region and a second cover end region secured to the intermediate member with a second living hinge,
wherein the cover is selectively adjustable between a closed configuration in which the cover member covers the base and an open configuration in which the base is substantially free of coverage from the cover member.

2. The cover of claim 1, wherein the slot defined by the plate includes:
a first portion proximate to the first base end region and having a first width; and
a second portion spaced from the first base end region and having a second width that is greater than the first width.

3. The cover of claim 2, wherein the slot defined by the plate further comprises a notch proximate to the second portion, the notch being sized to allow a screw to pass therethrough.

4. The cover of claim 1, wherein the cover member includes:
two opposing cover sidewalls extending at least partially between the first cover end region and the second cover end region; and
a cover body positioned between the two opposing cover sidewalls,
wherein when the cover is in the closed position, the two opposing cover sidewalls space the cover body from the plate of the base, the plate of the base and the cover member defining an interior region of the cover in the closed position sized to position at least a portion of the emergency alert station therein without the cover member contacting the emergency alert station.

5. The cover of claim 4, wherein:
the base includes two opposing base sidewalls extending at least partially between the first base end region and the second base end region, the plate and the slot defined by the plate are positioned between the two opposing base sidewalls; and
the two opposing base sidewalls are sized and positioned at the second base end region such that the intermediate member contacts the two opposing base sidewalls when the cover is in the closed position.

6. The cover of claim 5, wherein:
at least one base sidewall of the two opposing base sidewalls includes a base tab positioned on an outer surface of the at least one base sidewall; and
at least one cover sidewall of the two opposing cover sidewalls includes a cover tab positioned on an inner surface of the at least one cover sidewall to engage with the base tab when the cover is in the closed position.

7. The cover of claim 4, wherein the first living hinge is configured to bend such that the intermediate member and the plate are substantially perpendicular with the intermediate member when the cover is in the closed position.

8. The cover of claim 4, wherein the second living hinge is configured to bend such that the intermediate member and the cover body are substantially perpendicular when the cover is in the closed position.

9. The cover of claim 4, wherein the first living hinge and the second living hinge are configured to bend such that the intermediate member is substantially parallel and/or coplanar with the plate of the base and the cover body of the cover member when the cover is in the open position.

10. The cover of claim 4, wherein the second cover end region is shaped complementary to the intermediate member.

11. An emergency station cover assembly, comprising:
an emergency alert station comprising a station base configured to electrically couple to one or more wires or cables, the station base including a station plate, a station body extending from the station plate, a screw hole positioned on the station plate to secure the station base to a structure, and at least one of an actuator or a button configured to electrically couple to the one or more wires or cables; and
a cover secured or securable to the emergency alert station, comprising:
a base comprising a first base end region, a second base end region, and a plate defining a slot extending from the first base end region towards the second base end region, wherein the slot is sized to fit around a portion of the station base;
an intermediate member secured to the second end region of the base with a first living hinge; and
a cover member having a first cover end region and a second cover end region secured to the intermediate member with a second living hinge,
wherein the cover is selectively adjustable between a closed configuration in which the cover member covers the emergency alert station and an open configuration in which the emergency alert station is substantially free of coverage from the cover member.

12. The emergency station cover assembly of claim 11, wherein the slot defined by the plate includes:
a first portion proximate to the first base end region and having a first width; and
a second portion spaced from the first base end region and having a second width that is greater than the first width, wherein the slot is sized and shaped to snap fit around the portion of the station base with the station base positioned within the second portion of the slot.

13. The emergency station cover assembly of claim 12, wherein the slot defined by the plate further comprises a notch proximate to the second portion and positioned to align with the screw hole of the station plate, the notch being sized to allow a screw to pass therethrough.

14. The emergency station cover assembly of claim 11, wherein the cover member includes:
two opposing cover sidewalls extending at least partially between the first cover end region and the second cover end region; and
a cover body positioned between the two opposing cover sidewalls,
wherein when the cover is in the closed position, the two opposing cover sidewalls space the cover body from the plate of the base, the plate of the base and the cover member defining an interior region of the cover in the closed position sized to position the at least one of the actuator or the button of the emergency alert station therein without the cover member contacting the at least one of the actuator or the button.

15. The emergency station cover assembly of claim 14, wherein:
the base includes two opposing base sidewalls extending at least partially between the first base end region and the second base end region, the plate and the slot defined by the plate are positioned between the two opposing base sidewalls; and
the two opposing base sidewalls are sized and positioned at the second base end region such that the intermediate member contacts the two opposing base sidewalls when the cover is in the closed position.

16. The emergency station cover assembly of claim 15, wherein:
at least one base sidewall of the two opposing base sidewalls includes a base tab positioned on an outer surface of the at least one base sidewall; and
at least one cover sidewall of the two opposing cover sidewalls includes a cover tab positioned on an inner surface of the at least one cover sidewall to engage with the base tab when the cover is in the closed position.

17-20. (canceled)

21. A method of securing a cover to an emergency alert station, the method comprising:
positioning a portion of a station body of a station base of the emergency alert station within a slot defined by a plate of a cover base of the cover, the slot extending from a first base end region of the cover base towards a second base end region of the cover base, the station base being electrically coupled or coupleable to one or more wires or cables and including at least one of an actuator or a button electrically coupled or coupleable to the one or more wires or cables;
positioning a screw or nail through a notch in the plate of the cover base, the screw or nail being disposed through a hole in a station plate of the station base; and
adjusting the cover from an open position in which the emergency alert station is at least partially free of coverage from a cover member of the cover to a closed position in which the cover member covers the emergency alert station, wherein in the closed position an intermediate member secured between the cover member and the cover base is (1) angled relative to the cover base through a first living hinge connecting the intermediate member and the cover base and (2) angled relative to the cover member through a second living hinge connecting the intermediate member and the cover member.

22. The method of claim 21, wherein:
the slot defined by the plate includes:
a first portion proximate to the first base end region and having a first width; and
a second portion spaced from the first base end region and having a second width that is greater than the first width; and
positioning a portion of the station body within the slot defined by the plate includes positioning the station body within the second portion of the slot.

23. The method of claim 21, wherein the cover member includes:
two opposing cover sidewalls extending at least partially between the first cover end region and the second cover end region; and
a cover body positioned between the two opposing cover sidewalls,
wherein when the cover is in the closed position, the two opposing cover sidewalls space the cover body from the plate of the cover base, the plate of the cover base and the cover member defining an interior region of the cover in the closed position sized to position the at least one of the actuator or the button of the emergency alert station therein without the cover member contacting the at least one of the actuator or the button.

24-29. (canceled)

30. The method of claim 21, wherein:
the station base is electrically coupled to the one or more wires or cables; and
the steps of (1) positioning the portion of the station body within the slot defined by the plate of the cover base, (2) positioning a screw or nail through a notch in the plate of the cover base, and (3) adjusting the cover from the open position to the closed position are performed without disconnecting the one or more wires or cables from the station base.
